(19) United States
(12) Patent Application Publication
(10) Pub. No.: US 2024/0330536 A1
(43) Pub. Date: Oct. 3, 2024

(54) Computer Systems and Methods for Intelligent Clash Detection and Resolution

(71) Applicant: Procore Technologies, Inc., Carpinteria, CA (US)

(72) Inventors: David McCool, Carpinteria, CA (US); Patrick Lardin, Santa Barbara, CA (US)

(21) Appl. No.: 18/194,451

(22) Filed: Mar. 31, 2023

(51) Int. Cl. G06F 30/20; G06F 30/18; G06Q 10/0631; G06Q 50/08

(52) U.S. Cl. CPC G06F 30/20; G06F 30/18; G06Q 10/06312; G06Q 50/08

(57) ABSTRACT

A method for intelligent clash resolution involves (1) receiving, from an end-user device associated with a user, an indication of a request to identify clashes between objects within a 3D model for a construction project, (2) based on the indication of the request, identifying a clash between a first object and a second object within the 3D model for the construction project, (3) based on (i) respective object metadata for the first object and the second object and (ii) historical data from one or more other construction projects, determining a solution for resolving the identified clash that comprises relocating the first object and not the second object, (4) and causing the end-user device to present an indication of the determined solution for resolving the identified clash.

### BACKGROUND

Construction projects are complex undertakings that involve intensive planning, design, and implementation throughout several discrete construction phases. For instance, a construction project typically commences with a design phase, where architects design the overall shape and layout of a construction project, such as a building. Next, engineers engage in a planning phase where they take the architects' designs and produce engineering drawings and plans for the construction of the project. At this stage, engineers may also design various portions of the project's infrastructure, such as HVAC (heating, ventilation, and air conditioning), plumbing, electrical, etc., and produce plans reflecting these designs as well. After, or perhaps in conjunction with, the planning phase, contractors may engage in a logistics phase to review these plans and begin to allocate various resources to the project, including determining what materials to purchase, scheduling delivery, and developing a plan for carrying out the actual construction of the project. Finally, during a construction phase, construction professionals begin to construct the project based on the finalized plans.

### Overview

Prior to beginning the construction phase, construction professionals typically engage in a rigorous review of construction project design information in order to resolve conflicts that could cause issues during construction. One such type of conflict that requires resolution prior to construction is an object clash. An object clash occurs when two or more designed objects of a construction project occupy the same space, such as piping that is inadvertently routed through ductwork, as one example. Such clashes are identified through a process known as “clash detection.”

Design information about a construction project may be visually represented by a three-dimensional (3D) model of the construction project, which may be embodied in a computerized form, such as a building information model (BIM) file. Software technology has been developed to facilitate identifying clashes for a construction project, whereby a 3D model of a construction project is analyzed to detect clashes between objects of the construction project. For instance, Procore Technologies, Inc. (“Procore”), who is the assignee of the present application, offers a construction management software application that includes a clash detection tool that facilitates identifying clashes within a 3D model of a construction project.

After clashes have been identified, construction professionals involved in the construction project can then begin a process known as “clash resolution,” which comprises determining solutions for identified clashes. Problematic clashes must be resolved and the construction project design information must be revised accordingly before construction for the construction project can begin.

Clash resolution typically involves reviewing identified clashes, determining which clashes need to be resolved, and then for each clash that needs to be resolved, determining which object should stay in place and which object(s) should be relocated. For instance, for a given clash involving piping and ductwork, the resolution may comprise a determination that the ductwork should remain in place and the location and/or positioning of the piping should be adjusted.

In practice, clash resolution is a largely manual process that is laborious and time-consuming and typically involves intensive coordination meetings between various construction professionals, whereby each detected clash is reviewed, potential solutions for the clash are discussed, and a resolution for the clash is determined. This approach for clash resolution presents several challenges. For example, because the number of clashes detected for a construction project can be large (e.g., hundreds of clashes, thousands of clashes, etc.), clash resolution can span several days, weeks, or even months.

As another example, construction professionals might rely on system-based prioritization for resolving clashes, which might involve determining an order of priority for the various systems of the construction project and then resolving clashes between objects by determining that the object from a higher priority system should stay in place and the object(s) from a lower priority system should be relocated. For instance, an order of priority may indicate that structural elements (e.g., walls, beams, columns, etc.) should take priority over HVAC elements, which should take priority over piping elements, which should take priority over electrical elements, and so on, as one possible example. Based on that order of priority, a clash between a particular air duct and a particular pipe would be resolved in favor of the air duct. However, such a system-based prioritization scheme fails to consider other factors that may be useful in determining how to resolve a clash, such as how much a particular solution would cost, how long a particular solution would take to complete, or availability of parts and materials that would be required for a particular solution, which can lead to resolutions that end up creating adverse consequences down the road.

As yet another example, the construction professionals that are responsible for clash resolution sometimes have limited visibility regarding the feasibility of a particular solution, which could otherwise help inform resolution of a particular clash. For instance, those construction professionals may not have knowledge about availability of construction crews that may be required for a particular solution, knowledge about exceptions to the system-based prioritizations scheme, or other practical knowledge that might render a particular solution impractical.

To help address these and other problems, disclosed herein is new software technology for intelligent clash detection and clash resolution.

As will be described in detail further below, the disclosed software technology includes various aspects, which may be implemented either individually or in combination. For instance, the disclosed software technology may include one or more software systems or subsystems that may run independently of each other and at different times, or may run in conjunction with one another, such as in instances where an output of one software system or subsystem forms part of an input for another software system or subsystem. Other examples are also possible.

In one aspect, the disclosed software technology comprises a first software subsystem that functions to identify clashes within a 3D model of a construction project. In another aspect, the disclosed software technology comprises a second software subsystem that functions to determine solutions for resolving identified clashes. In yet another aspect, the disclosed software technology comprises a software tool that enables users to interact with objects implicated in an identified clash in order to evaluate different solutions for resolving the identified clash.

Accordingly, in one aspect, disclosed herein is a method carried out by a computing platform that involves (1) receiving, from an end-user device associated with a user, an indication of a request to identify clashes between objects within a 3D model for a construction project, (2) based on the indication of the request, identifying a clash between a first object and a second object within the 3D model for the construction project, (3) based on (i) respective object metadata for the first object and the second object and (ii) historical data from one or more other construction projects, determining a solution for resolving the identified clash that comprises relocating the first object and not the second object, and (4) causing the end-user device to present an indication of the determined solution for resolving the identified clash.

In another aspect, disclosed herein is a computing platform that includes a network interface, at least one processor, a non-transitory computer-readable medium, and program instructions stored on the non-transitory computer-readable medium that are executable by the at least one processor to cause the computing platform to carry out one or more of the functions disclosed herein, including but not limited to the functions of the foregoing method.

In yet another aspect, disclosed herein is a non-transitory computer-readable storage medium that is provisioned with program instructions that, when executed by at least one processor, cause a computing platform to carry out one or more of the functions disclosed herein, including but not limited to the functions of the foregoing method.

One of ordinary skill in the art will appreciate these as well as numerous other aspects in reading the following disclosure.

### BRIEF DESCRIPTION OF THE DRAWINGS

FIG. 1 depicts an example network configuration in which example embodiments may be implemented.

FIG. 2 depicts a structural diagram of an example computing platform that may be configured to carry out one or more of the functions according to the disclosed software technology.

FIG. 3 depicts a structural diagram of an example end-user device that may be configured to communicate with the example computing platform of FIG. 2 and also carry out one or more functions in accordance with aspects of the disclosed technology.

FIG. 4 depicts an example computing environment that includes various computing subsystems for performing intelligent clash detection and resolution in accordance with aspects of the disclosed technology.

FIG. 5 depicts a logical diagram of an example clash detection subsystem in accordance with aspects of the disclosed technology.

FIG. 6A depicts a perspective view of a portion of a three-dimensional model showing a clash between objects.

FIG. 6B depicts a two-dimensional view of the clash between objects shown in FIG. 6A.

FIG. 7 depicts a logical diagram of an example clash resolution subsystem. in accordance with aspects of the disclosed technology.

FIG. 8A depicts an example of a recommended resolution for the clash between objects shown in FIG. 6A.

FIG. 8B depicts another example of a recommended resolution for the clash between objects shown in FIG. 6A.

FIG. 9 depicts a flowchart of an example process that may be carried out to facilitate intelligent clash detection and resolution in accordance with aspects of the disclosed technology.

Features, aspects, and advantages of the presently disclosed technology may be better understood with regard to the following description, appended claims, and accompanying drawings, as listed below. The drawings are for the purpose of illustrating example embodiments, but those of ordinary skill in the art will understand that the technology disclosed herein is not limited to the arrangements and/or instrumentality shown in the drawings.

### DETAILED DESCRIPTION

The following disclosure makes reference to the accompanying figures and several example embodiments. One of ordinary skill in the art should understand that such references are for the purpose of explanation only and are therefore not meant to be limiting. Part or all of the disclosed systems, devices, and methods may be rearranged, combined, added to, and/or removed in a variety of manners, each of which is contemplated herein.

### I. Example Network Configuration

The present disclosure is generally directed to new software technology for intelligent clash detection and clash resolution. At a high level, the disclosed software technology may function to (i) receive input indicating a scope for identifying clashes, (ii) based on the input, identify a set of clashes, (iii) for each identified clash, determine at least one recommended solution for resolving the clash, and (iv) cause the recommended solution to be presented at an end-user device, among various other functions that are described in further detail below. This disclosed software technology may be incorporated into one or more software applications that may take any of various forms.

As one possible implementation, this software technology may be incorporated into a software as a service (“SaaS”) application that includes both front-end software running on one or more end-user devices that are accessible to individuals associated with construction projects (e.g., contractors, subcontractors, project managers, architects, engineers, designers, etc., each of which may be referred to generally herein as a “construction professional”) and back-end software running on a back-end computing platform (sometimes referred to as a “cloud” platform) that interacts with and/or drives the front-end software, and which may be operated (either directly or indirectly) by the provider of the front-end software. As another possible implementation, this software technology may be incorporated into a software application that takes the form of front-end client software running on one or more end-user devices without interaction with a back-end computing platform. The software technology disclosed herein may be incorporated into software applications that take other forms as well. Further, such front-end client software may take various forms, examples of which may include a native application (e.g., a mobile application), a web application running on an end-user device, and/or a hybrid application, among other possibilities.

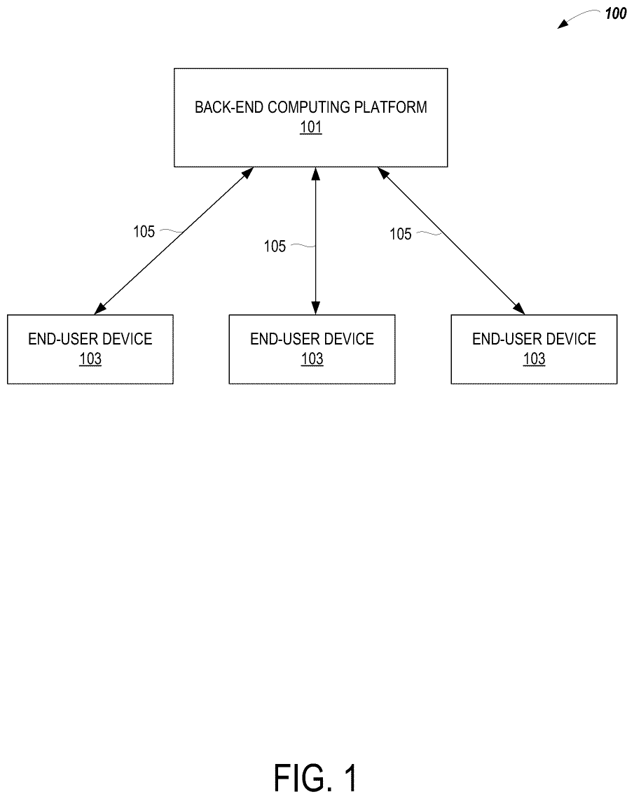

Turning now to the figures, FIG. 1 depicts an example network configuration 100 in which example embodiments of the present disclosure may be implemented. As shown in FIG. 1, network configuration 100 includes a back-end computing platform 101 that may be communicatively coupled to one or more end-user devices, depicted here, for the sake of discussion, as end-user devices 103.

Broadly speaking, the back-end computing platform 101 may comprise one or more computing systems that have been provisioned with software for carrying out one or more of the functions disclosed herein, including but not limited to functions related to receiving and evaluating project data, causing information to be displayed via a front-end interface (e.g., a graphical user interface (GUI)) through which the data is presented on the one or more end-user devices, and determining recommendations for presentation to a user. The one or more computing systems of the back-end computing platform 101 may take various forms and be arranged in various manners.

For instance, as one possibility, the back-end computing platform 101 may comprise computing infrastructure of a public, private, and/or hybrid cloud (e.g., computing and/or storage clusters) that has been provisioned with software for carrying out one or more of the functions disclosed herein. In this respect, the entity that owns and operates back-end computing platform 101 may either supply its own cloud infrastructure or may obtain the cloud infrastructure from a third-party provider of “on demand” computing resources, such as Amazon Web Services (AWS) or the like. As another possibility, the back-end computing platform 101 may comprise one or more dedicated servers that have been provisioned with software for carrying out one or more of the functions disclosed herein. Other implementations of the back-end computing platform 101 are possible as well.

In turn, end-user devices 103 may each be any computing device that is capable of running the front-end software disclosed herein. In this respect, the end-user devices 103 may each include hardware components such as a processor, data storage, a communication interface, and user-interface components (or interfaces for connecting thereto), among other possible hardware components, as well as software components that facilitate the end-user device's ability to run the front-end software incorporating the features disclosed herein (e.g., operating system software, web browser software, mobile applications, etc.). As representative examples, end-user devices 103 may each take the form of a desktop computer, a laptop, a netbook, a tablet, a smartphone, and/or a personal digital assistant (PDA), among other possibilities.

As further depicted in FIG. 1, the back-end computing platform 101 may be configured to interact with the end-user devices 103 over respective communication paths 105. In this respect, each communication path 105 between the back-end computing platform 101 and an end-user device 103 may generally comprise one or more communication networks and/or communications links, which may take any of various forms. For instance, each respective communication path 105 with the back-end computing platform 101 may include any one or more of point-to-point links, Personal Area Networks (PANs), Local-Area Networks (LANs), Wide-Area Networks (WANs) such as the Internet or cellular networks, cloud networks, and/or operational technology (OT) networks, among other possibilities. Further, the communication networks and/or links that make up each respective communication path 105 with the back-end computing platform 101 may be wireless, wired, or some combination thereof, and may carry data according to any of various different communication protocols. Although not shown, the respective communication paths 105 between the end-user devices 103 and the back-end computing platform 101 may also include one or more intermediate systems. For example, it is possible that the back-end computing platform 101 may communicate with a given end-user device 103 via one or more intermediary systems, such as a host server (not shown). Many other configurations are also possible.

While FIG. 1 shows an arrangement in which three particular end-user devices are communicatively coupled to the back-end computing platform 101, it should be understood that this is merely for purposes of illustration and that any number of end-user devices may communicate with the back-end computing platform 101.

Although not shown in FIG. 1, the back-end computing platform 101 may also be configured to receive data, such as data related to a construction project, from one or more external data sources, such as an external database and/or another back-end computing platform or platforms. Such data sources—and the data output by such data sources—may take various forms.

It should be understood that the network configuration 100 is one example of a network configuration in which embodiments described herein may be implemented. Numerous other arrangements are possible and contemplated herein. For instance, other network configurations may include additional components not pictured and/or more or less of the pictured components.

### II. Example Back-End Computing Platform

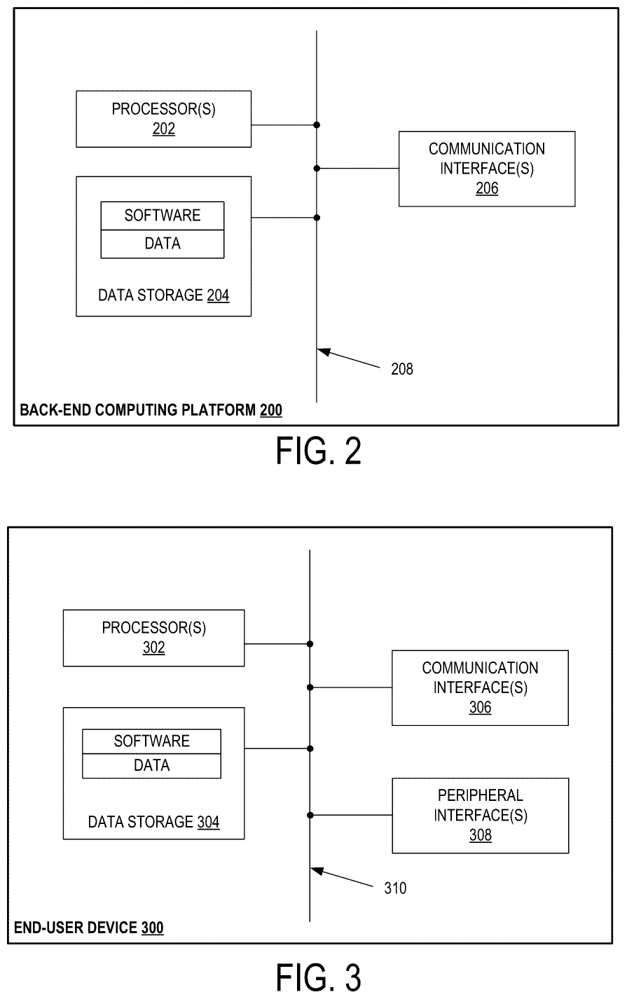

FIG. 2 is a simplified block diagram illustrating some structural components that may be included in an example back-end computing platform 200, which could serve as, for instance, the back-end computing platform 101 of FIG. 1. In line with the discussion above, the back-end computing platform 200 may generally comprise one or more computer systems (e.g., one or more servers), and these one or more computer systems may collectively include at least a processor 202, data storage 204, and a communication interface 206, all of which may be communicatively linked by a communication link 208 that may take the form of a system bus, a communication network such as a public, private, or hybrid cloud, or some other connection mechanism.

Processor 202 may comprise one or more processor components, such as general-purpose processors (e.g., a single- or multi-core microprocessor), special-purpose processors (e.g., an application-specific integrated circuit or digital-signal processor), programmable logic devices (e.g., a field programmable gate array), controllers (e.g., microcontrollers), and/or any other processor components now known or later developed. In line with the discussion above, it should also be understood that processor 202 could comprise processing components that are distributed across a plurality of physical computing devices connected via a network, such as a computing cluster of a public, private, or hybrid cloud.

In turn, data storage 204 may comprise one or more non-transitory computer-readable storage mediums that are collectively configured to store (i) program instructions that are executable by processor 202 such that the back-end computing platform 200 is configured to perform some or all of the functions disclosed herein, which may be arranged together into software applications, virtual machines, software development kits, toolsets, or the like, and (ii) data that may be received, derived, or otherwise stored, for example, in one or more databases, file systems, or the like, by the back-end computing platform 200 in connection with the disclosed functions. In this respect, the one or more non-transitory computer-readable storage mediums of data storage 204 may take various forms, examples of which may include volatile storage mediums such as random-access memory, registers, cache, etc. and non-volatile storage mediums such as read-only memory, a hard-disk drive, a solid-state drive, flash memory, an optical-storage device, etc. In line with the discussion above, it should also be understood that data storage 204 may comprise computer-readable storage mediums that are distributed across a plurality of physical computing devices connected via a network, such as a storage cluster of a public, private, or hybrid cloud. Data storage 204 may take other forms and/or store data in other manners as well.

Communication interface 206 may be configured to facilitate wireless and/or wired communication with external data sources and/or end-user devices, such as one or more end-user devices 103 of FIG. 1. Additionally, in an implementation where the back-end computing platform 200 comprises a plurality of physical computing devices connected via a network, communication interface 206 may be configured to facilitate wireless and/or wired communication between these physical computing devices (e.g., between computing and storage clusters in a cloud network). As such, communication interface 206 may facilitate communications according to any of various communications protocols, examples of which may include Ethernet, Wi-Fi, cellular network, serial bus (e.g., Firewire, USB 3.0, etc.), short-range wireless protocols, and/or any other communication protocol that provides for wireless and/or wired communication. Communication interface 206 may also include multiple communication interfaces of different types. Other configurations are possible as well.

Although not shown, the back-end computing platform 200 may additionally include or have one or more interfaces for connecting to user-interface components that facilitate user interaction with the back-end computing platform 200, such as a keyboard, a mouse, a trackpad, a display screen, a touch-sensitive interface, a stylus, a virtual-reality headset, and/or speakers, among other possibilities, which may allow for direct user interaction with the back-end computing platform 200. Further, although not shown, an end-user device, such as one or more of the end-user devices 103, may include similar components to the back-end computing platform 200, such as a processor, a data storage, and a communication interface. Further, the end-user device may also include or be connected to a device, such as a smartphone, a laptop, a tablet, or a desktop, among other possibilities, that includes integrated user interface equipment, such as a keyboard, a mouse, a trackpad, a display screen, a touch-sensitive interface, a stylus, a virtual-reality headset, speakers, etc., which may allow for direct user interaction with the back-end computing platform 200.

It should be understood that the back-end computing platform 200 is one example of a computing platform that may be used with the embodiments described herein. Numerous other arrangements are possible and contemplated herein. For instance, other computing platforms may include additional components not pictured and/or more or fewer of the pictured components.

### III. Example End-User Device

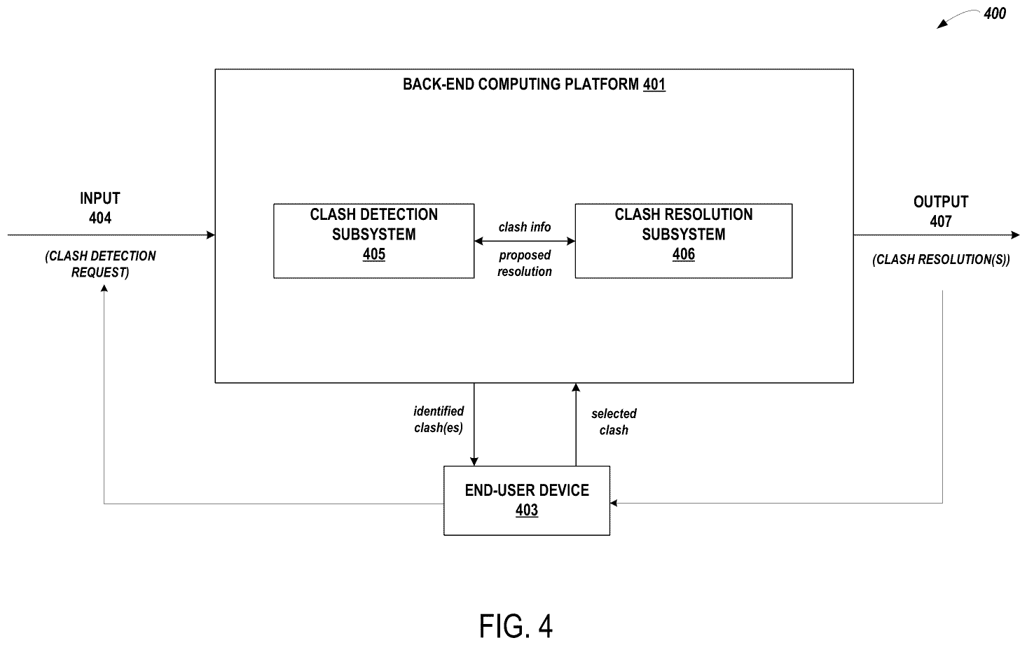

Turning now to FIG. 3, a simplified block diagram is provided to illustrate some structural components that may be included in an example end-user device 300, which may serve as an end-user device 103 described above with reference to FIG. 1. As shown in FIG. 3, the end-user device 300 may include one or more processors 302, data storage 304, one or more communication interfaces 306, and one or more peripheral interfaces 308, all of which may be communicatively linked by a communication link 310 that may take the form of a system bus or some other connection mechanism. Each of these components may take various forms.

The one or more processors 302 may comprise one or more processing components, such as general-purpose processors (e.g., a single- or a multi-core CPU), special-purpose processors (e.g., a GPU, application-specific integrated circuit, or digital-signal processor), programmable logic devices (e.g., a field programmable gate array), controllers (e.g., microcontrollers), and/or any other processor components now known or later developed.

The data storage 304 may comprise one or more non-transitory computer-readable storage mediums that are collectively configured to store (i) program instructions that are executable by the processor(s) 302 such that the end-user device 300 is configured to perform certain functions related to interacting with and accessing services provided by a computing platform, such as the example back-end computing platform 200 described above with reference to FIG. 2, and (ii) data that may be received, derived, or otherwise stored, for example, in one or more databases, file systems, repositories, or the like, by the end-user device 300, related to interacting with and accessing the services provided by the computing platform. In this respect, the one or more non-transitory computer-readable storage mediums of the data storage 304 may take various forms, examples of which may include volatile storage mediums such as random-access memory, registers, cache, etc., and non-volatile storage mediums such as read-only memory, a hard-disk drive, a solid-state drive, flash memory, an optical-storage device etc. The data storage 304 may take other forms and/or store data in other manners as well.

The one or more communication interfaces 306 may be configured to facilitate wireless and/or wired communication with other computing devices. The one or more communication interfaces 306 may take any of various forms, examples of which may include an Ethernet interface, a serial bus interface (e.g., Firewire, USB 3.0, etc.), a chipset and antenna adapted to facilitate wireless communication, and/or any other interface that provides for any of various types of wireless communication (e.g., Wi-Fi communication, cellular communication, short-range wireless protocols, etc.) and/or wired communication. Other configurations are possible as well.

The end-user device 300 may additionally include or have one or more peripheral interfaces for connecting to an electronic peripheral that facilitates user interaction with the end-user device 300, such as a keyboard, a mouse, a trackpad, a display screen, a touch-sensitive interface, a stylus, a virtual-reality headset, and/or one or more speaker components, among other possibilities.

It should be understood that the end-user device 300 is one example of an end-user device that may be used to interact with a computing platform as described herein and/or perform one or more of the functions described herein. Numerous other arrangements are possible and contemplated herein. For instance, in other embodiments, the end-user device 300 may include additional components not pictured and/or more or fewer of the pictured components.

### IV. Example Functionality

As mentioned above, disclosed herein is new software technology that improves upon existing software technology for clash detection and provides new software technology for intelligent clash resolution.

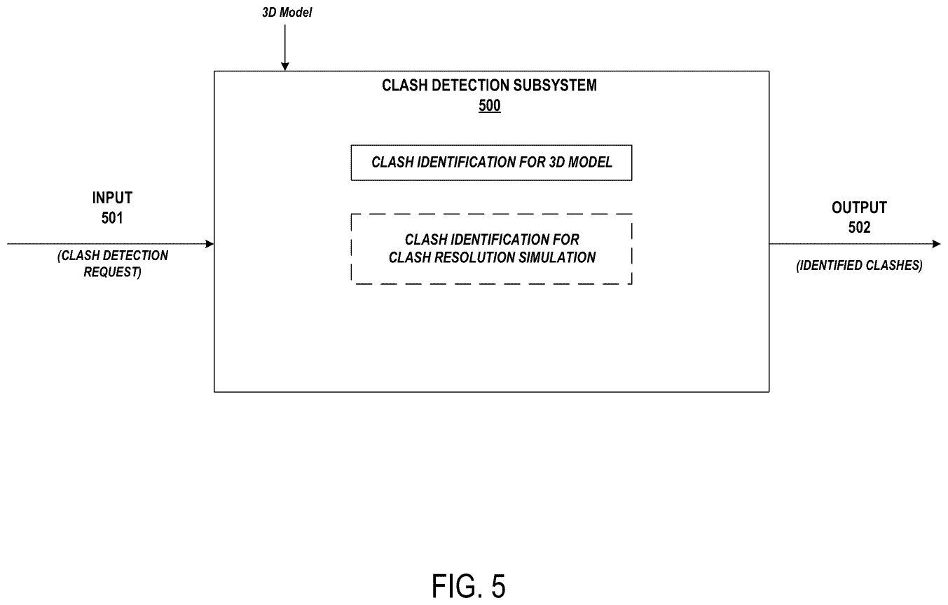

FIG. 4 depicts an example computing environment 400 that includes various computing subsystems that may be configured to implement the disclosed software technology and perform operations related to one or more techniques disclosed herein. For instance, the computing environment 400 may include a back-end computing platform 401 that is configured to run the software technology disclosed herein. In this regard, the back-end computing platform 401 may resemble or be the same as the back-end computing platform 101 shown in FIG. 1. The back-end computing platform 401 may comprise a “clash detection” subsystem 405 and a “clash resolution” subsystem 406. Further, the computing environment 400 may include an end-user device 403 that is configured to communicate with the back-end computing platform 401. For instance, the end-user device may resemble or be the same as one of the end-user devices 103 shown in FIG. 1.

The end-user device 403 may be configured to receive user input indicating a clash detection request and provide an indication of the clash detection request to the back-end computing platform 401. The indication of the clash detection request may serve as an input 404 to the clash detection subsystem 405, which may generally function to identify clashes within a 3D model of a construction project, which may also form part of the input 404. The back-end computing platform 401 may cause the end-user device 403 to present a representation of clashes identified by the clash detection subsystem 405. The end-user device 403 may receive user input indicating a given clash and may then provide an indication of the given clash to the back-end computing platform 401. The indication of the given clash may serve as input for the clash resolution subsystem 406, which may generally function to analyze information including (i) data about objects implicated in the given clash (e.g., object metadata) and (ii) historical clash resolution data involving similar objects and thereby determine a recommended solution for resolving the given clash, which may form an output 407. The output 407 may be provided at least to the end-user device 403, which may present a representation of the determined solution for resolving the given clash.

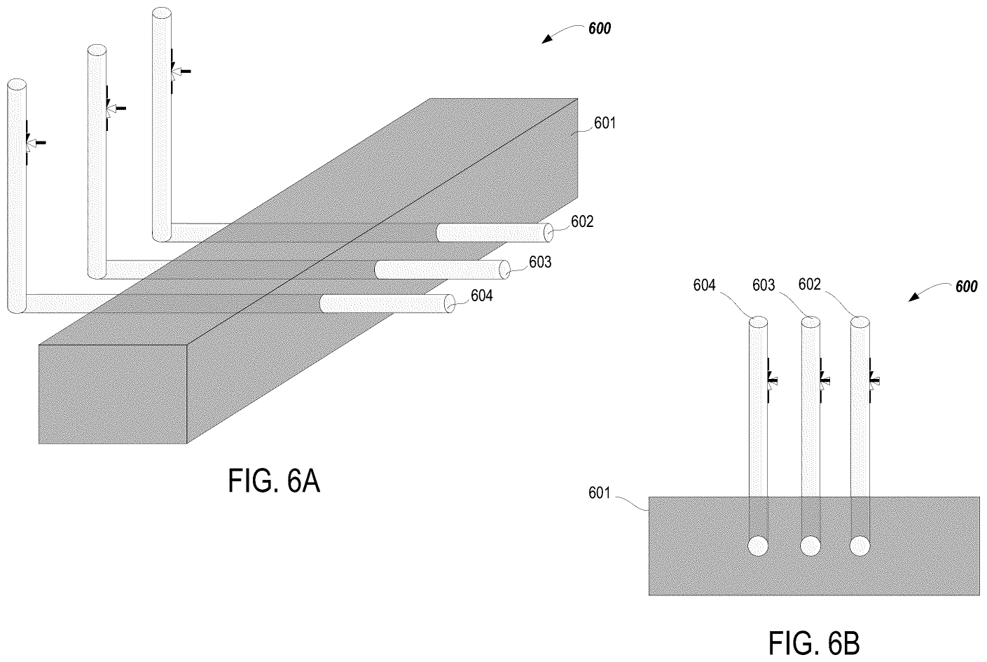

Each of the clash detection and clash resolution subsystems 405 and 406 and their respective functionalities will be described in more detail below with reference to FIGS. 5-9.

As mentioned above, in one aspect, the disclosed software technology comprises a first software subsystem, which may be referred to herein as a clash detection subsystem. FIG. 5 depicts a logical diagram of an example clash detection subsystem 500 that may be configured to carry out at least some of the functionality disclosed herein. The clash detection subsystem 500 may resemble the clash detection subsystem 405 of the back-end computing platform 401 shown in FIG. 4. Like the clash detection subsystem 405, the clash detection subsystem 500 may be operated by a back-end computing platform (not shown in FIG. 5) that is configured to run a construction management software application that incorporates the clash detection subsystem 500.

In general, the clash detection subsystem 500 may be configured to (i) receive, as an input 501, a request to identify clashes within a 3D model of a construction project, (ii) identify one or more clashes based on the request, and (iii) provide, as an output 502, an indication of the one or more identified clashes within the 3D model of the construction project. The input 501 and the output 502 may take various forms.

In one implementation, the input 501 may comprise a clash detection request that comprises a request to identify clashes within the 3D model of the construction project based on one or more user-defined characteristics. For instance, in practice, a user (e.g., a construction professional) may use an end-user device to communicate with the back-end computing platform to access a user interface of the construction management software application, navigate to one or more user interface views for inputting clash detection requests, and input a new clash detection request.

The one or more user interface views for inputting the new clash detection request may enable the construction professional to provide user input indicating one or more characteristics based on which clashes should be identified. In practice, certain clashes, such as ductwork being routed through a wall, or a column intersecting a floor and/or ceiling, are inherent to a construction project and do not need to be resolved. Therefore, the construction professional may wish to focus the clash detection request on those clashes which will likely need resolution. The one or more characteristics may generally define a scope for identifying clashes and may take various forms.

As one example, the one or more characteristics may indicate a given area (e.g., a floor, a room, a hallway, etc.) of the construction project within which clashes are to be identified. As another example, the one or more characteristics may indicate a type of system (e.g., HVAC, medical gas, etc.) for which clashes are to be identified. As yet another example, the one or more characteristics may indicate types of objects (e.g., ducts, pipes, etc.) between which clashes are to be identified. Further yet, as another example, the one or more characteristics may indicate a combination of the above (e.g., all clashes between ducts and med gas piping).

Based on the user input provided by the construction professional indicating a clash detection request and/or identifying the one or more characteristics, the end-user device may provide an indication of the clash detection request, including the one or more characteristics based on which clashes in the 3D model of the construction project should be identified, to the back-end computing platform. The indication of the clash detection request may comprise the input 501 that is provided to the clash detection subsystem 500. Based on the one or more characteristics included in the request, the clash detection subsystem 500 may analyze the 3D model of the construction project and identify one or more clashes. In turn, the back-end computing platform may cause the end-user device associated with the construction professional to display a representation of each identified clash. The representations of the identified clashes may collectively form the output 502.

In another implementation, the input 501 may comprise a request to predict clashes that may be created by a given resolution. For instance, as will be explained further below, the disclosed technology may comprise a clash resolution simulation software tool that enables a user to interact with objects implicated in an identified clash and evaluate different solutions for resolving the identified clash. For instance, the user may be able to select a first object in an identified clash involving two objects and simulate a potential solution for resolving the clash that involves relocating the first object, such as by moving the first object to a different position and/or location in which the first object no longer clashes with a second object. In such an implementation, the clash detection subsystem 500 may be configured to simulate the potential solution and identify any new clashes that would be caused by the simulated solution. The clash detection subsystem 500 may then provide, as an output 502, an indication of any new clashes that would be created by the simulated solution. As will be explained below, each potential solution that the construction professional simulates may be provided as a respective input 501 based on which the clash detection subsystem 500 may identify, as a respective output 502, one or more new clashes that would be caused if the potential solution were to be implemented.

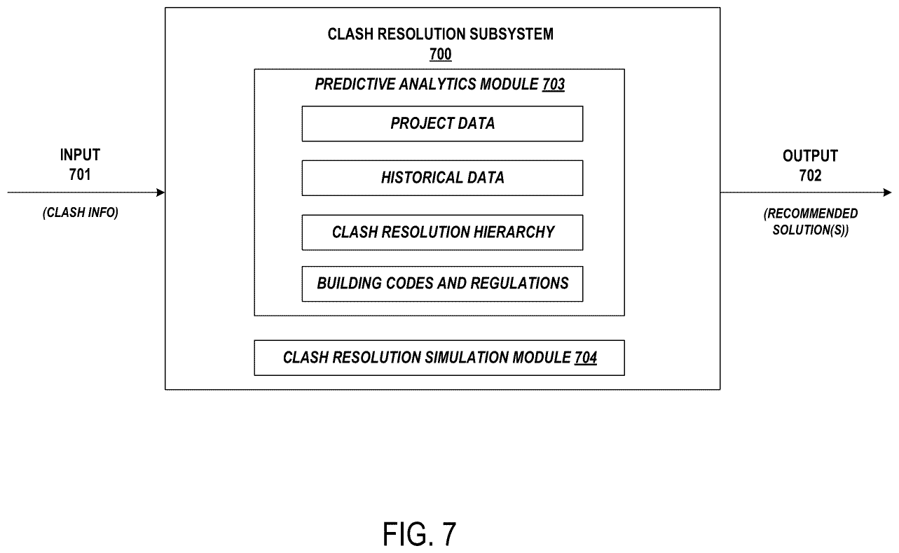

FIGS. 6A and 6B depict different views of an example clash 600 that may be identified by the clash detection subsystem 500 in line with the discussion above. The clash 600 may involve an air duct 601 and three medical gas (“med gas”) pipes 602, 603, and 604. For instance, in the example of FIGS. 6A and 6B, the clash 600 may be identified in a 3D model of a construction project for a healthcare facility, such as a hospital or a medical clinic. FIG. 6A depicts a three-dimensional perspective view of the clash 600, and FIG. 6B depicts a two-dimensional view of the clash 600 as seen from a right-side of the air duct 601 shown in FIG. 6A. As can be seen in FIGS. 6A and 6B, the air duct 601 and the med gas pipes 602-604, as represented within the 3D model for the construction project, occupy the same space, with the med gas pipes 602-604 inadvertently passing through a section of the air duct 601.

In line with the discussion above, an existing approach for resolving a clash such as the clash 600 shown in FIGS. 6A and 6B would typically involve one or more construction professionals reviewing the clash 600 during a clash resolution coordination meeting and determining a solution for resolving the clash 600 based on one or more factors. For instance, a previously-determined system-based priority scheme for resolving clashes might not include med gas piping, as it is a less common object to be installed. Consequently, the one or more construction professionals may rely on their own experience to estimate the easiest resolution for the clash. In this regard, the one or more construction professionals may consider that smaller objects are generally easier to relocate than larger objects, and generally create fewer new clashes as a result of their relocation. As a result, the one or more construction professionals may determine that the clash 600 is to be resolved by relocating the med gas pipes 602-604 a certain number of inches upward or downward so as to route the pipes around the air duct 601, and the designs for the construction project may be updated accordingly. However, resolving the clash 600 by relocating the med gas pipes 602-604 may end up being a much more costly and time-intensive solution than relocating the air duct 601 would have been.

Medical gas piping is used to supply various types of gasses that are used during medical treatment. Indeed, medical gas piping is strictly regulated by federal and/or municipal codes. For instance, piping that is used to supply medical gasses must be made out of certain material, must conform to a certain size, and must maintain a certain pressure for airflow. Further, medical gas piping systems need to comprise a continuous supply system throughout a facility in order to provide an uninterrupted gas supply, and the individual pipes of a medical gas piping system connect to various supply sources, such as tanks or compressors, situated throughout the system. Further yet, medical gas piping systems must include adequate alarm systems to provide prompt and ample warning in the event of a gas leak. Still further, medical gas piping systems should be installed by experienced vendors who are knowledgeable about applicable regulations and requirements. Moreover, to ensure that medical gas piping systems meet safety requirements, many cities require inspection of plans and/or installation for medical gas piping systems.

With that in mind, a clash resolution that involves relocating med gas pipes, such as the med gas pipes 602-604, could cause unintended adverse consequences for the construction project. As one example, if the clash is not detected until construction has already begun, relocating the med gas pipes could create safety hazards by disrupting the continuity of the medical gas piping system, which may then require re-installation of at least some parts of the medical gas piping system and/or other systems that may be impacted. As another example, at the time of construction, regulation-specific piping parts that would be required to update the routing of pipes 602-604 in accordance with the determined resolution may be unavailable or difficult to obtain. Each of these consequences and others could result in significantly increased costs and/or scheduling delays for the construction project. However, such consequences may not be apparent at the time of determining a resolution for the clash 600 during a conflict resolution coordination meeting.

As mentioned above, to address the shortcomings in existing approaches for clash resolution, in another aspect, disclosed herein is new software technology for intelligent clash resolution. The disclosed software technology comprises a second software subsystem, which may be referred to herein as a clash resolution subsystem.

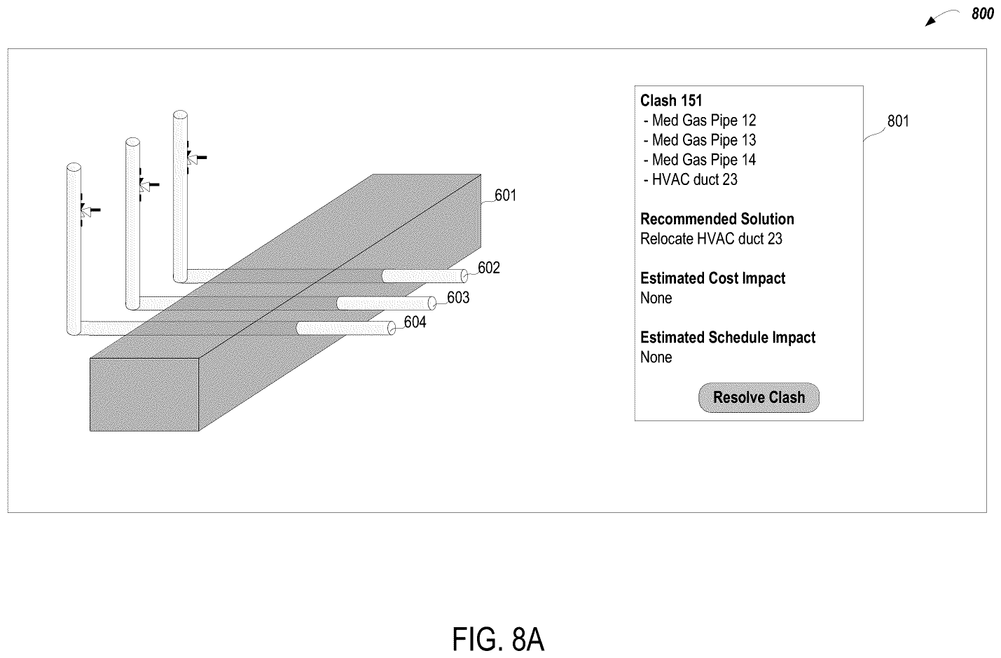

FIG. 7 depicts a logical diagram of an example clash resolution subsystem 700 that may be configured to carry out at least some of the functionality disclosed herein. The clash resolution subsystem 700 may resemble the clash resolution subsystem 406 of the back-end computing platform 401 shown in FIG. 4. Like the clash resolution subsystem 406, the clash resolution subsystem 700 may be operated by a back-end computing platform (not shown in FIG. 7) that is configured to run a construction management software application that incorporates the clash resolution subsystem 700.

The clash resolution subsystem 700 may generally function to (i) receive, as input, an indication of a request to resolve a clash involving at least two objects, (ii) analyze information about each object involved in the clash and historical clash resolution data from other construction projects, and (iii) based on the analysis, determine and output a solution for resolving the identified clash, which may involve relocating a given object involved in the clash.

In some implementations, the clash resolution subsystem 700 may additionally communicate with an end-user device associated with a construction professional to cause the end-user device to present the determined solution to the construction professional.

Further, in some implementations, the clash resolution subsystem 700 may additionally comprise a software tool that enables users to interact with objects involved in an identified clash in order to evaluate different solutions for resolving the identified clash. In such implementations, the clash resolution subsystem may further function to communicate with the clash detection subsystem disclosed herein to provide the clash detection subsystem with an indication of a potential solution proposed by a user, receive information about new clashes that would be created as a result of implementing the proposed solution, and cause an indication of the new clashes to be presented to the user.

In one implementation, the input 701 may comprise data defining a clash based on user input that is provided via a user interface for requesting clash resolutions. For instance, a back-end computing platform, such as the back-end computing platform 401, that is responsible for running a software application incorporating the disclosed technology including the example clash resolution subsystem 700 may cause an end-user device (e.g., an end-user device 403) associated with a construction professional to display one or more user interface views for requesting a clash resolution. In practice, the one or more user interface views for requesting a clash resolution may be accessed by the construction professional launching the software application (e.g., a mobile application, a native desktop application, or a web-based version of the application, etc.) via the end-user device, which may be configured to communicate with the back-end computing platform. The construction professional may then navigate to a user interface view that enables selection of identified clashes and provide a user input indicating a given clash. Based on the user input, the end-user device may then transmit to the back-end computing platform data defining the given clash, which may then serve as the input 701 for the clash resolution subsystem 700.

In other implementations, the input 701 may be generated by the back-end computing platform without direct user input, based on the clash detection subsystem 500 outputting identified clashes. The input 701 may be generated in other ways as well.

The data defining the clash that is provided as the input 701 to the clash resolution subsystem 700 may take various forms. As one example, the data defining the clash may comprise metadata about each object involved in the clash. For instance, the metadata may indicate identifying information for each object involved in the clash, such as a respective object identifier, a respective object type, and/or a respective construction system with which the object is associated, perhaps along with other information. The data defining the clash may take other forms as well.

The input 701 may then be provided to the clash resolution subsystem 700 for evaluation.

As shown in FIG. 7, the clash resolution subsystem 700 may comprise one or more software modules that function to perform various tasks. For instance, the predictive analytics module 703 may function to evaluate the input 701, along with other information, in order to return the output 702.

The predictive analytics module 703 may comprise program code that functions to apply predictive analytics to the input 701 in order to determine a solution for resolving the clash. The predictive analytics module 703 that may be utilized by the clash resolution subsystem 700 to determine a resolution for the clash may take any of various forms. In general, the predictive analytics module 703 may utilize a machine learning model that is trained using one or more machine learning techniques (including but not limited to artificial and/or recurrent neural networks, regression, and/or clustering, etc.).

As one possibility, the predictive analytics module 703 may comprise a machine learning model that functions to (1) receive, as input, (i) data about the given construction project, (iii) historical clash resolution data for other construction projects, and perhaps also (iii) clash resolution hierarchy information and (iv) information about building codes, standards, and/or regulations, (2) evaluate the received data to determine a solution for resolving the given clash, and (3) output one or more recommended solutions for resolving the given clash.

The data about the given construction project that may be evaluated by the machine learning model may take various forms. In general, such information may comprise any information about the given construction project that is available to the back-end computing platform. For example, as one possibility, the data about the given construction project may comprise metadata about each object involved in the given clash, which may take various forms, including a respective object identifier for the object, an object type for the object, and/or a construction system with which the object is associated. The metadata about each object may take other forms as well.

As another possibility, the data about the given construction project may comprise scheduling information associated with the given project, such as a master schedule that indicates when certain milestones for the given construction project are scheduled for completion, or other schedules that indicate when certain project tasks are scheduled for commencement and completion. As another example, such information may comprise information about personnel availability, including availability of construction crews. As yet another example, such information may comprise cost and availability information for each object associated with the given construction project, which may include cost and availability of materials and/or cost of labor for installing the object. Such information about the given construction project may take other forms as well.

The historical clash resolution data that may be evaluated by the machine learning model may include data from previous construction projects that have been completed or are concurrently underway, and may be provided to the machine learning model on an ongoing basis as construction projects continue to progress. Further, the historical clash resolution data may include various types of data.

As one possibility, the historical clash resolution data may comprise historical cost data. As one example, historical cost data may indicate an average increase in cost that was associated with relocating each type of object that was involved in a clash. For instance, the historical cost data may indicate an approximate increase in cost to relocate the first type of object (e.g., $10 per foot of relocated material), which may be based on costs for materials (e.g., additional fittings, etc.). Further, the historical cost data may indicate that relocating the second type of object tends to result in a much lower or even near zero increase in cost, which may be due to the flexibility of installation of the second type of object. Based on analyzing such historical data, in a situation where the input 701 indicates that the given clash involves the first type of object and the second type of object, the clash resolution subsystem 700 may determine that resolving the given clash by relocating the second type of object may be more cost-effective than relocating the first type of object.

As yet another example, historical cost data may indicate a cost of labor associated with installing each type of object included in a previous construction project, as well as the marginal increase in the cost of labor associated with relocating each type of object that was involved in a clash. For instance, using the example described above, the historical cost of labor data may indicate that relocating the first type of object tends to result in an increase in cost of labor to install the first type of object (e.g., $20 per foot of relocated material), which may account for additional bends, fittings, etc. that are often installed with relocated objects However, the historical cost of labor data may indicate that the second type of object tends to result in a much lower or even near zero increase in the cost of labor. Based on analyzing such historical data, in a situation where the input 701 indicates that the given clash involves the first type of object and the second type of object, the clash resolution subsystem 700 may determine that resolving the given clash by relocating the first type of object may have an overall lesser impact on costs for the given construction project than relocating the second type of object.

As another possibility, the historical clash resolution data may comprise scheduling data. As one example, scheduling data may indicate scheduling changes that were caused by resolving a clash by relocating a given type of object. For instance, such scheduling data may indicate that resolving a clash by relocating a first type of object often resulted in significant delays in the construction project because relocating the first type of object tends to result in cascading coordination issues with related objects. Based on analyzing such scheduling data, when determining a solution for a given clash that involves the first type of object, the clash resolution subsystem 700 may determine that relocating the first type of object would likely cause scheduling delays for the given construction project and may thus determine that a second type of object involved in the given clash should be relocated instead.

In some implementations, the historical clash resolution data that may be evaluated by the machine learning model may also include information related to clash resolutions for the given construction project itself, which may further inform solutions that are recommended by the clash resolution subsystem 700. For instance, construction professionals may be able to provide ongoing input and/or updates on clash resolutions. For example, a first clash resolution for a first clash of the given construction project that was recommended by the clash resolution subsystem 700 may have been accepted and the design information for the given construction project may have been updated accordingly. However, at a later time, based on updated information or knowledge, it may be determined that a second resolution for the first clash is more appropriate (e.g., perhaps based on updated cost, material, and/or labor information for the first or second resolutions), and a construction professional may provide user input indicating that the first clash is to be resolved in accordance with the second resolution (e.g., by updating the resolution using the disclosed software tool as will be further described below). The clash resolution subsystem 700 may then evaluate the updated clash resolution information for the first clash when determining clash resolutions for other clashes that may involve the same type of objects or systems. Other examples are also possible.

The historical clash resolution data may comprise other data as well.

The clash resolution hierarchy information that may be utilized by the machine learning model may take various forms. For instance, as one possibility, the clash resolution hierarchy information may comprise an order of priority based on which the clash resolution subsystem 700 is to determine a solution for resolving the given clash. For instance, as one example, the order of priority may comprise a system-based order of priority that dictates how objects from different construction systems should be prioritized when determining a solution for resolving a given clash. In some implementations, the order of priority may indicate one or more exceptions to the system-based order of priority. As another example, the order of priority may comprise a characteristic-based order of priority that dictates how various characteristics of an object involved in a given clash should be prioritized when determining a solution for resolving the given clash. Such object characteristics may take various forms, such as an estimated cost impact for relocating the object, or an estimated schedule impact for relocating the object. For instance, the order of priority may indicate that cost impacts should be prioritized over scheduling impacts, such that a solution resulting in an increased cost to the given construction project should be prioritized over a solution resulting in a scheduling delay for the given construction project. The clash resolution hierarchy information may take other forms as well.

The information about building codes, standards, and/or regulations that may be utilized by the machine learning model may take various forms. In general, such information may comprise any industry and/or legal requirements that dictate how buildings should be constructed. These requirements may address safety standards, sustainability standards, and also geographical and/or meteorological conditions of a particular geographical area and may be set by various entities, such as governmental entities, professional organizations tasked with researching, evaluating, and/or setting industry standards, or a combination thereof. For instance, in the United States, national and local legal codes enacted by government authorities may dictate minimum requirements for how structural, plumbing, HVAC, natural gas, and other systems of residential and commercial buildings should be designed and constructed. Such legal codes may be informed by industry-specific standards and guidelines. For instance, organizations like the International Code Council (ICC), the American National Standards Institute (ANSI), the National Fire Protection Association (NFPA), the American Society of Civil Engineers (ASCE), the Sheet Metal and Air Conditioning Contractors' National Association (SMACNA), the American Society of Heating and Air Conditioning Engineers (ASHAE), the Occupational Safety and Health Administration (OSHA) have defined guidelines and regulations for the construction industry that address various standards, including health and safety, inspections, environmental controls, protective equipment, and more. Many other examples exist. The machine learning model may be trained using such requirements and may utilize that information when determining clash resolutions. For instance, the clash resolution subsystem 700 may determine that a first solution for a given clash is likely to create a safety hazard that breaks compliance with a building code or safety regulation and may thus determine that a second solution for resolving the given clash should be recommended. Other examples are also possible.

The function of evaluating the data received as input and thereby determining a solution for resolving the given clash may take various forms. For instance, in one implementation, the clash resolution subsystem 700 may evaluate the received data as described above and determine that relocating a given object involved in the given clash would have a lower cost impact and less adverse scheduling impact based on historical cost and scheduling data associated with objects of a type similar to the type of objects involved in the given clash.

In another implementation, the clash resolution subsystem 700 may evaluate the received data as described above and calculate a respective predicted cost impact and a respective predicted scheduling impact for each object in the given clash. The clash resolution subsystem 700 may then compare the respective predicted cost impacts and the respective predicted scheduling impacts to identify which object of the given clash would have a less overall adverse impact if it were to be relocated. The clash resolution subsystem 700 may then determine that resolving the given clash should comprise relocating the identified object. In this respect, the clash resolution subsystem 700 may utilize one or more other estimation techniques to determine the predicted cost and/or scheduling impacts for each object in the given clash. For instance, as one example, the clash resolution subsystem 700 may utilize an assembly-based estimation tool to determine the predicted cost and/or scheduling impacts for each object in the given clash.

To illustrate with an example, consider the clash 600 of FIG. 6A in an implementation where the clash resolution subsystem 700 is configured to estimate a respective predicted cost impact and a respective predicted scheduling impact for each object in the given clash. The clash resolution subsystem 700 may determine a respective predicted cost impact for each pipe 602-604 by calculating the cost of materials and labor required to add additional piping equipment to each pipe in order to re-route the pipe below the air duct 601. Such costs might include the cost of additional med gas piping material that would be required to direct each pipe 602-604 down and around the bottom of the air duct 601, as well as connectors that would be required to connect the joints of the pipes 602-604 with the additional piping material. Further, such costs might include the cost of labor that would be required to install any additional piping material and/or fittings based on the measurements of the air duct and available space for re-routing the pipes.

Similarly, the clash resolution subsystem 700 may determine a respective predicted cost impact and predicted scheduling impact for relocating the air duct 601. The clash resolution subsystem 700 may then compare the predicted cost and scheduling impacts to determine whether the air duct 601 or the med gas pipes 602-604 should be relocated.

Determining the solution for resolving the given clash may take other forms as well.

After determining the solution for resolving the given clash, the clash resolution subsystem 700 may output the solution for resolving the given clash. The function of outputting the determined solution may take various forms.

As one possibility, outputting the determined solution may comprise causing the end-user device associated with the construction professional to present an indication of the determined solution. For instance, the clash resolution subsystem 700 may cause the end-user device to present an indication recommending that a given object of the given clash should be relocated in order to resolve the given clash. The clash resolution subsystem 700 may further cause the end-user device to present options for one or more actions that the construction professional may take to facilitate resolution of the given clash based on the determined solution. For instance, the clash resolution subsystem 700 may cause the end-user device to present an option that enables the construction professional to implement the recommended solution, which may in turn cause the back-end computing platform to take one or more actions, such as causing a notification regarding the given clash and the determined solution to be transmitted to one or more other construction professionals that are responsible for updating construction project design and/or plan information.

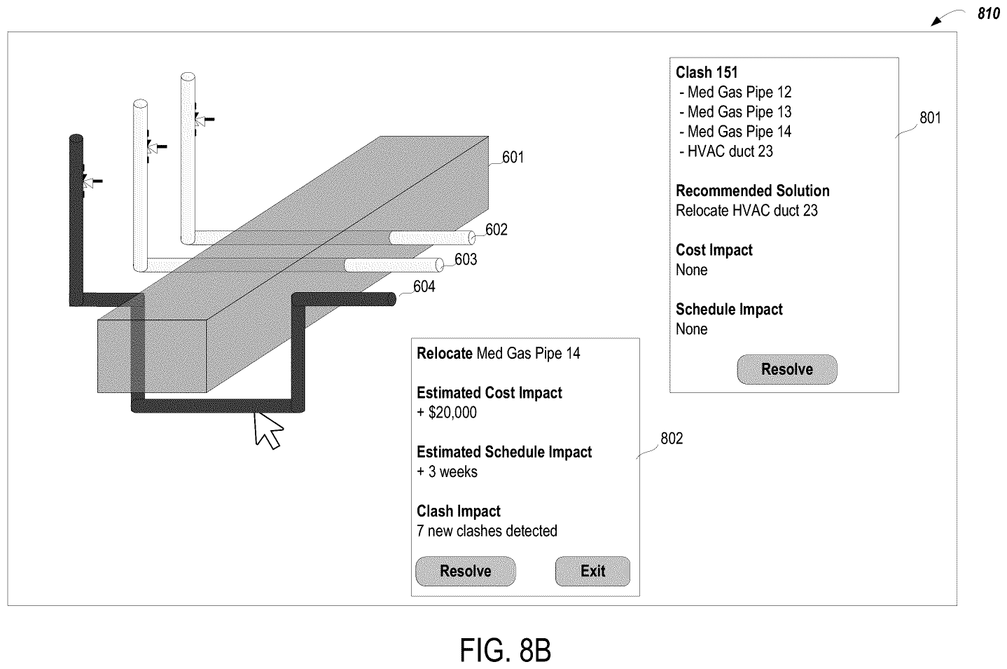

As another possibility, outputting the determined solution may comprise causing the end-user device associated with the construction professional to present an indication of the determined solution along with information about an estimated cost impact and/or an estimated scheduling impact for the determined solution. To illustrate, FIG. 8A depicts one example of such a user interface view 800 that may be displayed at the end-user device of the construction professional. The user interface view 800 may include a visual representation of the given clash, which, in the example of FIG. 8A, may be the clash 600 shown in FIG. 6A. Further, the example user interface view 800 may include an indication 801 (which may take various forms, such as an overlay, a pane, or a pop-up window, etc.) that includes information about the clash 600, along with a recommended solution for resolving the clash 600, an estimated cost impact, and an estimated scheduling impact. As can be seen in FIG. 8A, the information about the clash 600 includes identifying information for the clash 600 (“Clash 151”), and a listing of the objects involved in the clash 600 (“Med Gas Pipes 12, 13, and 14”, “HVAC Duct 23”). Further, the indication 801 includes a recommended solution for resolving the clash 600, which indicates that the HVAC Duct 23 should be relocated. Further yet, the indication 801 indicates that there is no estimated cost impact or estimated scheduling impact for resolving the clash 600 by relocating the HVAC Duct 23. Still further, the indication 801 includes a selectable option to “Resolve Clash,” which may be selected by the construction professional to facilitate the process of resolving the clash 600 in accordance with the solution determined by the clash resolution subsystem 700.

As yet another possibility, outputting the determined solution may comprise launching the clash resolution simulation module 704 of the clash resolution subsystem 700 shown in FIG. 7 and causing the end-user device associated with the construction professional to display an interactive software tool that enables the construction professional to view a given clash and interact with different objects of the given clash and simulate different solutions for resolving the given clash in order to evaluate the cost and scheduling impacts of different solutions. To illustrate, FIG. 8B depicts one example of such a user interface view 810 comprising the interactive software tool that may be displayed at the end-user device of the construction professional. Like the user interface view 800 of FIG. 8A, the user interface view 810 may include a visual representation of the given clash—which, in the example of FIG. 8B, may be the clash 600—and the indication 801 that includes information about the clash 600, a recommended solution for resolving the clash 600, and an estimated cost impact and an estimated scheduling impact for resolving the clash 600 in accordance with the recommended solution.

Additionally, the software tool depicted in the user interface view 810 may enable the construction professional to select different objects in the clash 600 in order to evaluate different solutions for resolving the clash 600. For instance, as shown in FIG. 8B, the construction professional may have selected the med gas pipe 604 to simulate resolving the clash 600 by relocating the med gas pipe 604. The software tool may further enable the construction professional to define how the med gas pipe 604 should be relocated for the simulation. As shown in FIG. 8B, the construction professional may have provided user input by dragging down the portion of the med gas pipe 604 that was previously intersecting the air duct 601 so that it is instead routed downward and around the air duct 601. Based on the user input, the clash resolution subsystem 700 may have calculated an estimated cost impact and an estimated scheduling impact for the resolution simulated by the construction professional. Furthermore, the clash resolution subsystem 700 may have communicated with the clash detection subsystem 500 to cause the clash detection subsystem 500 to identify any potential clashes that may be created as a result of relocating the med gas pipe 604 as defined by the construction professional. Thereafter, the clash resolution subsystem 700 may have caused the end-user device to display an indication 802 that includes information about the simulated resolution, an estimated cost impact, an estimated scheduling impact, and a clash impact based on the simulated resolution. As shown in FIG. 8A, the indication 802 indicates that resolving the clash 600 by routing the med gas pipe 604 around the bottom edge of the air duct 601 would likely cost an extra $20,000 and take an additional 3 weeks to complete. Further, the indication 802 indicates that resolving the clash 600 by routing the med gas pipe 604 around the bottom edge of the air duct 601 would create seven new clashes. Lastly, the indication 802 may include an option to “Exit” the simulation mode for the med gas pipe 604 (whereupon the construction professional might select a different object in the clash 600 for simulating a different resolution) and an option to “Resolve” the clash 600 in accordance with the simulated resolution proposed by the construction professional (whereupon the construction professional might be presented with options for facilitating resolution of the clash 600). The user interface view 810 may take other forms as well.

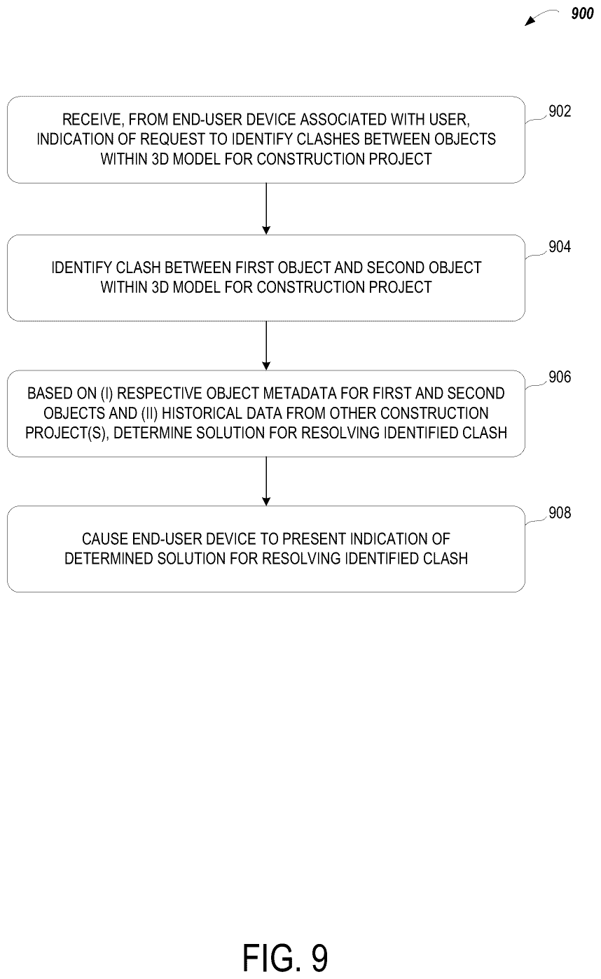

Turning now to FIG. 9, a flowchart of an example process 900 is shown that illustrates one example implementation of operations that may be carried out to facilitate intelligent clash detection and resolution as discussed herein. The example process 900 may include one or more operations, functions, or actions as illustrated by one or more of steps 902-908. Although steps 902-908 are illustrated in sequential order, these steps may also be performed in parallel, and/or in a different order than those described herein. Also, the various steps may be combined into fewer steps, divided into additional steps, and/or removed based upon the desired implementation. Furthermore, in the examples below, the operations discussed in relation to FIG. 9 may be described as being performed by a certain computing device, such as a computing platform in communication with at least one end-user device, such as the back-end computing platform 101 in communication with an end-user device 103 shown in FIG. 1, or the back-end computing platform 401 in communication with the end-user device 403 shown in FIG. 4. However, it should be understood that any of the operations discussed herein might be carried out by some combination of a back-end computing platform and/or an end-user device, or by an end-user device by itself.

Beginning at block 902, the back-end computing platform may receive, from an end-user device associated with a user, an indication of a request to identify clashes between objects within a 3D model for a construction project. For example, the indication of a request to identify clashes may take the form of an input 404 shown in FIG. 4 or an input 501 shown in FIG. 5 and discussed above, although the indication of the request might take other forms as well.

At block 904, based on the indication of the request, the back-end computing platform may identify a clash between a first object and a second object within the 3D model for the construction project. For instance, the back-end computing platform may include a clash-detection subsystem, such as the clash detection subsystem 405 shown in FIG. 4 or the clash detection subsystem 500 shown in FIG. 5 and discussed above. The clash detection subsystem may function to compare the geometries of competing objects within the 3D model as indicated in the request, and thereby identify a clash between the first object and the second object.

At block 906, based at least on (i) respective object metadata for the first object and the second object and (ii) historical data from one or more other construction projects, the back-end computing platform may determine a solution for resolving the identified clash that comprises relocating the first object and not the second object. As noted above, the object metadata may take various forms, including a type of object (e.g., duct, pipe, electrical conduit, etc.) for the first and second objects. Similarly, the historical data from one or more other construction projects may also take various forms, including clashes between the same two types of objects on other construction projects, cost information for the two types of objects, among other possibilities. Based on this information, a clash resolution subsystem, such as the clash resolution subsystem 406 shown in FIG. 4 or the clash resolution subsystem 700 shown in FIG. 7, may determine a solution for resolving the identified clash.

At block 908, in line with the discussion above, the back-end computing platform may cause the end-user device to present an indication of the determined solution for resolving the identified clash.

FIG. 9 includes one or more operations, functions, or actions as illustrated by one or more of operational blocks. Although the blocks are illustrated in a given order, some of the blocks may also be performed in parallel, and/or in a different order than those described herein. Also, the various blocks may be combined into fewer blocks, divided into additional blocks, and/or removed based upon the desired implementation.

In addition, for the flowcharts shown in FIG. 9 and other processes and methods disclosed herein, the diagrams show functionality and operation of one possible implementation of present embodiments. In this regard, each block may represent a module, a segment, or a portion of program code, which includes one or more instructions executable by one or more processors for implementing logical functions or blocks in the process.

The program code may be stored on any type of computer readable medium, for example, such as a storage device including a disk or hard drive. The computer readable medium may include non-transitory computer readable medium, for example, such as computer-readable media that stores data for short periods of time like register memory, processor cache and Random Access Memory (RAM). The computer readable medium may also include non-transitory media, such as secondary or persistent long-term storage, like read only memory (ROM), optical or magnetic disks, compact-disc read only memory (CD-ROM), for example. The computer readable media may also be any other volatile or non-volatile storage systems. The computer readable medium may be considered a computer readable storage medium, for example, or a tangible storage device. In addition, for the processes and methods disclosed herein, each block in FIG. 9 may represent circuitry and/or machinery that is wired or arranged to perform the specific functions in the process.

### V. CONCLUSION

Example embodiments of the disclosed innovations have been described above. Those skilled in the art will understand, however, that changes and modifications may be made to the embodiments described without departing from the true scope and spirit of the present invention, which will be defined by the claims.

Further, to the extent that examples described herein involve operations performed or initiated by actors, such as “humans,” “operators,” “users,” or other entities, this is for purposes of example and explanation only. Claims should not be construed as requiring action by such actors unless explicitly recited in claim language.

1. A computing platform comprising:
a network interface;
at least one processor;
a non-transitory computer-readable medium; and
program instructions stored on the non-transitory computer-readable medium that are executable by the at least one processor such that the computing platform is configured to:
receive, from an end-user device associated with a user, an indication of a request to identify clashes between objects within a 3D model for a construction project;
based on the indication of the request, identify a clash between a first object and a second object within the 3D model for the construction project;
based on (i) respective object metadata for the first object and the second object and (ii) historical data from one or more other construction projects, determine a solution for resolving the identified clash that comprises relocating the first object and not the second object; and
cause the end-user device to present an indication of the determined solution for resolving the identified clash.

2. The computing platform of claim 1, wherein the program instructions that are executable by the at least one processor such that the computing platform is configured to determine the solution for resolving the identified clash comprise program instructions that are executable by the at least one processor such that the computing platform is configured to:
determine a simulated relocation of the first object within the 3D model for the construction project; and
identify one or more new clashes between the first object and one or more other objects within the 3D model that would result if the first object is relocated according to the simulated relocation.

3. The computing platform of claim 1, wherein the respective object metadata comprises a respective type of object for the first object and the second object, and wherein the historical data from the one or more other construction projects comprises one or both of material cost information or labor cost information for the respective types of objects.

4. The computing platform of claim 3, wherein:
the computing platform further comprises program instructions that are executable by the at least one processor such that the computing platform is configured to:
based on one or both of the material cost information or the labor cost information, determine (i) an estimated cost for relocating the first object and (ii) an estimated cost for relocating the second object; and
the program instructions that are executable by the at least one processor such that the computing platform is configured to determine the solution for resolving the identified clash comprise program instructions that are executable by the at least one processor such that the computing platform is configured to:
determine that the first estimated cost is less than the second estimated cost.

5. The computing platform of claim 1, wherein the respective object metadata comprises a respective type of object for the first object and the second object, and wherein the historical data comprises data associated with clashes involving one or both of the first type of object or the second type of object.

6. The computing platform of claim 1, wherein the program instructions that are executable by the at least one processor such that the computing platform is configured to determine the solution for resolving the identified clash comprise program instructions that are executable by the at least one processor such that the computing platform is configured to:
based on (iii) information related to a schedule for the construction project, determine that relocating the first object will cause a lesser delay to the schedule for the construction project than relocating the second object.

7. The computing platform of claim 1, wherein the determined solution is a first determined solution, the computing platform further comprising program instructions that are executable by the at least one processor such that the computing platform is configured to:
based on (i) the respective object metadata for the first object and the second object and (ii) the historical data from one or more other construction projects, determine a second solution for resolving the identified clash; and
wherein the program instructions that are executable by the at least one processor such that the computing platform is configured to cause the end-user device to present the indication of the first determined solution comprise program instructions that are executable by the at least one processor such that the computing platform is configured to cause the end-user device to present a comparison of the first determined solution with the second determined solution.

8. A non-transitory computer-readable medium, wherein the non-transitory computer-readable medium is provisioned with program instructions that, when executed by at least one processor, cause a computing platform to:
receive, from an end-user device associated with a user, an indication of a request to identify clashes between objects within a 3D model for a construction project;
based on the indication of the request, identify a clash between a first object and a second object within the 3D model for the construction project;
based on (i) respective object metadata for the first object and the second object and (ii) historical data from one or more other construction projects, determine a solution for resolving the identified clash that comprises relocating the first object and not the second object; and
cause the end-user device to present an indication of the determined solution for resolving the identified clash.

9. The non-transitory computer-readable medium of claim 8, wherein the program instructions that, when executed by at least one processor, cause the computing platform to determine the solution for resolving the identified clash comprise program instructions that, when executed by at least one processor, cause the computing platform to:
determine a simulated relocation of the first object within the 3D model for the construction project; and
identify one or more new clashes between the first object and one or more other objects within the 3D model that would result if the first object is relocated according to the simulated relocation.

10. The non-transitory computer-readable medium of claim 8, wherein the respective object metadata comprises a respective type of object for the first object and the second object, and wherein the historical data from the one or more other construction projects comprises one or both of material cost information or labor cost information for the respective types of objects.

11. The non-transitory computer-readable medium of claim 10, wherein:
the non-transitory computer-readable medium is also provisioned with program instructions that, when executed by at least one processor, cause the computing platform to:
based on one or both of the material cost information or the labor cost information, determine (i) an estimated cost for relocating the first object and (ii) an estimated cost for relocating the second object; and
the program instructions that, when executed by at least one processor, cause the computing platform to determine the solution for resolving the identified clash comprise program instructions that, when executed by at least one processor, cause the computing platform to:
determine that the first estimated cost is less than the second estimated cost.

12. The non-transitory computer-readable medium of claim 8, wherein the respective object metadata comprises a respective type of object for the first object and the second object, and wherein the historical data comprises data associated with clashes involving one or both of the first type of object or the second type of object.

13. The non-transitory computer-readable medium of claim 8, wherein the program instructions that, when executed by at least one processor, cause the computing platform to determine the solution for resolving the identified clash comprise program instructions that, when executed by at least one processor, cause the computing platform to:
based on (iii) information related to a schedule for the construction project, determine that relocating the first object will cause a lesser delay to the schedule for the construction project than relocating the second object.

14. The non-transitory computer-readable medium of claim 8, wherein the determined solution is a first determined solution, and wherein the non-transitory computer-readable medium is also provisioned with program instructions that, when executed by at least one processor, cause the computing platform to:
based on (i) the respective object metadata for the first object and the second object and (ii) the historical data from one or more other construction projects, determine a second solution for resolving the identified clash; and
wherein the program instructions that, when executed by at least one processor, cause the computing platform to cause the end-user device to present the indication of the first determined solution comprise program instructions that, when executed by at least one processor, cause the computing platform to cause the end-user device to present a comparison of the first determined solution with the second determined solution.

15. A method carried out by a computing platform, the method comprising:
receiving, from an end-user device associated with a user, an indication of a request to identify clashes between objects within a 3D model for a construction project;
based on the indication of the request, identifying a clash between a first object and a second object within the 3D model for the construction project;
based on (i) respective object metadata for the first object and the second object and (ii) historical data from one or more other construction projects, determining a solution for resolving the identified clash that comprises relocating the first object and not the second object; and
causing the end-user device to present an indication of the determined solution for resolving the identified clash.

16. The method of claim 15, wherein determining the solution for resolving the identified clash comprises:
determining a simulated relocation of the first object within the 3D model for the construction project; and
identifying one or more new clashes between the first object and one or more other objects within the 3D model that would result if the first object is relocated according to the simulated relocation.

17. The method of claim 15, wherein the respective object metadata comprises a respective type of object for the first object and the second object, and wherein the historical data from the one or more other construction projects comprises one or both of material cost information or labor cost information for the respective types of objects.

18. The method of claim 17, further comprising:
based on one or both of the material cost information or the labor cost information, determining (i) an estimated cost for relocating the first object and (ii) an estimated cost for relocating the second object,
wherein determining the solution for resolving the identified clash comprises determining that the first estimated cost is less than the second estimated cost.

19. The method of claim 15, wherein the respective object metadata comprises a respective type of object for the first object and the second object, and wherein the historical data comprises data associated with clashes involving one or both of the first type of object or the second type of object.

20. The method of claim 15, wherein determining the solution for resolving the identified clash comprises:
based on (iii) information related to a schedule for the construction project, determining that relocating the first object will cause a lesser delay to the schedule for the construction project than relocating the second object.
